(19) United States
(12) Patent Application Publication
(10) Pub. No.: US 2026/0293375 A1
(43) Pub. Date: Sep. 24, 2026

(54) LIGHT-EMITTING MESA FOR MICRO-LED AND METHOD FOR FORMING THE SAME, AND MICRO-LED CHIP

(71) Applicant: Hue Inc., Shanghai (CN)

(72) Inventor: Feng Feng, Shanghai (CN)

(73) Assignee: Hue Inc., Shanghai (CN)

(21) Appl. No.: 19/458,931

(22) Filed: Jan. 26, 2026

(30) Foreign Application Priority Data
Jan. 26, 2025 (CN) 202510124083.3

(51) Int. Cl. H10H 20/819; H10H 20/01

(52) U.S. Cl. CPC H10H 20/819; H10H 20/0133

(57) ABSTRACT

A light-emitting mesa for a micro-LED, a method for forming the same and a micro-LED chip are provided. The light-emitting mesa includes: a transparent conductive layer, arranged on a side of the light-emitting mesa facing away from the light extraction side; a first epitaxial layer, arranged between the transparent conductive layer and a light-emitting layer; a light-emitting layer, arranged between the first epitaxial layer and a second epitaxial layer and configured to emit light; and a second epitaxial layer, arranged on a side of the light-emitting mesa facing the light extraction side. An area of the second epitaxial layer is greater than an area of the first epitaxial layer. A side surface of the light-emitting mesa has an inclined surface. An inclination angle of the inclined surface is 55° to 75°.

### CROSS-REFERENCE TO RELATED APPLICATION

This application claims the priority benefit of Chinese application serial no. 202510124083.3, filed on Jan. 26, 2025. The entirety of the above-mentioned patent application is hereby incorporated by reference herein and made a part of this specification.

### BACKGROUND

### Technical Field

The present disclosure generally relates to the field of micro-LEDs, and more specifically relates to a light-emitting mesa for a micro-LED and a method for forming the same. Furthermore, the present disclosure also relates to a micro-LED chip having such a light-emitting mesa.

### Description of Related Art

Micro light-emitting diode (Micro-LED) is a new type LED structure obtained by thin-filming, miniaturizing, and arraying the original LED structure, which integrates the arrayed micro level micro LEDs on an active addressing drive panel to achieve the lighting and individual control of the micro-LEDs, thereby outputting the desired display image. The core structure of the micro-LED is a light-emitting mesa, which includes a PN junction diode, and the PN junction diode is composed of direct-bandgap semiconductor material. When the upper and lower electrodes apply a forward bias voltage to the micro-LED to allow current to pass through, electrons and holes recombine in the active area, and meanwhile emit monochromatic light photons.

The light-emitting mesa of the micro-LED includes a normally arranged trapezoidal light-emitting mesa and an upside-down arranged trapezoidal light-emitting mesa, wherein the upper surface of the normally arranged trapezoidal light-emitting mesa is smaller than the lower surface, while the case for the upside-down arranged trapezoidal light-emitting mesa is exactly the opposite. Currently, the etching of the upside-down arranged trapezoidal light-emitting mesa includes the following steps: first, an epitaxial wafer having an epitaxial layer is provided; then, a photoresist is coated on the surface of the epitaxial wafer, then the photolithography technology is used to transfer the designed mesa pattern onto the photoresist through a mask, and the areas that need to be etched to form the mesa are exposed, while the remaining areas are protected by the photoresist. Then, etching is performed to remove the material, for example, dry etching, such as reactive ion etching (RIE), or wet etching processes can be used to remove the exposed semiconductor material to form the light-emitting mesa structure. However, due to the vertical morphology of the photoresist, the inclination angle of the etched light-emitting mesa is relatively large, and approaches 90°. Furthermore, although the wet etching process has lower costs, the anisotropy of etching is relatively poor, which may lead to excessive tilting of the sidewalls of the mesa, and approaching 90°. Excessive inclination angle will affect the aperture ratio of the chip.

### SUMMARY

Starting from the prior art, the task of the present disclosure is to provide a light-emitting mesa for a micro-LED and a method for forming the same, and a micro-LED having such a light-emitting mesa, through the light-emitting mesa, the forming method, or the micro-LED chip, the aperture ratio of the micro-LED can be significantly improved, so that its light output is improved.

In the first aspect of the present disclosure, the aforementioned task is solved by a light-emitting mesa for a micro-LED, which includes:
a transparent conductive layer, a first epitaxial layer, a light-emitting layer and a second epitaxial layer arranged from a side of the light-emitting mesa facing away from a light extraction side toward a side of the light-emitting mesa facing the light extraction side,
where
the transparent conductive layer is arranged on the side of the light-emitting mesa facing away from the light extraction side;
the first epitaxial layer is arranged between the transparent conductive layer and the light-emitting layer;
the light-emitting layer is arranged between the first epitaxial layer and the second epitaxial layer, and the light-emitting layer is configured to emit light; and
the second epitaxial layer is arranged on the side of the light-emitting mesa facing the light extraction side, where an area of the second epitaxial layer is greater than an area of the first epitaxial layer, and a side surface of the light-emitting mesa has an inclined surface, and an inclination angle of the inclined surface is 55° to 75°.

In one embodiment of the present disclosure, the side surface of the transparent conductive layer has a first slope, and the first epitaxial layer has a second slope, where the first slope is not equal to the second slope.

In another embodiment of the present disclosure, the inclination angle of the inclined surface is 60° to 70°.

In another embodiment of the present disclosure, a side surface of the second epitaxial layer and a side surface of the light-emitting layer have a second slope, where corresponding inclination angles of the first slope and the second slope are both less than or equal to 70°.

In another embodiment of the present disclosure, the corresponding inclination angles of the first slope and the second slope are both less than or equal to 65°.

In another embodiment of the present disclosure, the light-emitting mesa further includes:
a temporary substrate, in contact with the second epitaxial layer.

In another embodiment of the present disclosure, the light-emitting mesa further includes:
a marking layer, arranged between the temporary substrate and the second epitaxial layer.

In another embodiment of the present disclosure, a thickness of the temporary substrate is 600 μm to 1000 μm; and/or a thickness of the marking layer is 4.4 μm to 5 μm.

In another embodiment of the present disclosure, a material of the marking layer is selected from a group that includes following items:
AlN, its thickness is 150 nm to 200 nm;
AlGaN, its thickness is 300 nm to 400 nm;
U-GaN, its thickness is 2300 nm to 2800 nm;
N-GaN, its thickness is 1000 nm to 1200 nm;
MQW, its thickness is 200 nm to 400 nm; and
P-GaN, its thickness is 100 nm to 200 nm.

In another embodiment of the present disclosure, a maximum width at two ends of the inclined surface of the light-emitting mesa is 1.4 μm to 1.7 μm.

In another embodiment of the present disclosure, a depth of the light-emitting mesa is 0.3 μm to 0.7 μm.

In another embodiment of the present disclosure, the second epitaxial layer includes:
a step portion, in electrical contact with the light-emitting layer; and
a base portion, extending from the step portion to two sides.

In another embodiment of the present disclosure, base portions of adjacent light-emitting mesas are connected with each other.

In another embodiment of the present disclosure, a thickness of the step portion is 400 nm to 800 nm; and/or a thickness of the base portion is 4 μm to 4.4 μm.

In another embodiment of the present disclosure, a thickness of the transparent conductive layer is 600 nm to 1500 nm; and/or
a thickness of the first epitaxial layer is 80 nm to 120 nm; and/or
a thickness of the light-emitting layer is 280 nm to 400 nm; and/or
a thickness of the second epitaxial layer is 180 nm to 220 nm.

In another embodiment of the present disclosure, a side surface of the transparent conductive layer has a first inclined edge. Side surfaces of the first epitaxial layer, the light-emitting layer, and the second epitaxial layer have a second inclined surface, where
an end of the first inclined edge is connected with an end of the second inclined surface; or
a horizontal distance between the end of the first inclined edge and the end of the second inclined surface is less than or equal to 200 nm.

In another embodiment of the present disclosure, the first inclined edge has a first inclination angle X, and the second inclined surface has a second inclination angle Y, where the first inclination angle X and the second inclination angle Y satisfy following relationship:
d=(X*d1+Y*d2)/(d1+d2);
60°≤d≤70°,
where
d1 is a thickness of the transparent conductive layer,
d2 is a sum of the thicknesses of the first epitaxial layer, the light-emitting layer, and the second epitaxial layer, and
d is an average inclination angle of the light-emitting mesa over an entire thickness.

In another embodiment of the present disclosure, a material of the transparent conductive layer is selected from a group comprising:
indium tin oxide, zinc oxide, or cadmium tin oxide.

In another embodiment of the present disclosure, a material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P, where the first conductivity type is different from the second conductivity type.

In another embodiment of the present disclosure, the light-emitting layer includes a multi-quantum-well layer, where the multi-quantum-well layer is an InGaN/GaN multi-quantum-well layer, an InGaN/AlGaN multi-quantum-well layer, an InGaAs/AlGaAs multi-quantum-well layer, or an AlGaInP multi-quantum-well layer.

In another embodiment of the present disclosure, an electron blocking layer is arranged on a first side of the light-emitting layer, and the first side is a side of the light-emitting layer of a same direction or an opposite direction of a light emission.

In the second aspect of the present disclosure, the aforementioned task is solved by a micro-LED chip, the micro-LED chip includes:
the light-emitting mesa according to the present disclosure;
an insulating layer, configured to accommodate the light-emitting mesa and through-hole contact portions;
a drive circuit, provided with a metal layer on a surface of the drive circuit, the drive circuit is provided with a plurality of through-hole contact portions, and the through-hole contact portions are electrically connected with the metal layer, and an array area of the micro-LED chip is bonded onto the drive circuit through a bottom conductive bonding layer, where the drive circuit further includes a wiring stacked layer below the metal layer, which is configured to lead out a first electrode;
a first electrode, being electrically connected with the through-hole contact portions and being led out of the wiring stacked layer;
a passivation layer, covering at least a part of the side surface of the light-emitting mesa;
a bottom transparent conductive layer, located on a surface of the passivation layer and in electrical contact with the second epitaxial layer; and
a second electrode, located on a surface of the transparent conductive layer.

In one embodiment of the present disclosure, the second electrode is a circular reflective electrode arranged around the light-emitting mesa.

In another embodiment of the present disclosure, a polarity of the second electrode is opposite to a polarity of the first electrode.

In another embodiment of the present disclosure, a material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P, where the first conductivity type is different from the second conductivity type.

In another embodiment of the present disclosure, the light-emitting layer includes a multi-quantum-well layer, where the multi-quantum-well layer is an InGaN/GaN multi-quantum-well layer, an InGaN/AlGaN multi-quantum-well layer, an InGaAs/AlGaAs multi-quantum-well layer, or an AlGaInP multi-quantum-well layer.

In another embodiment of the present disclosure, an electron blocking layer is arranged on a first side of the light-emitting layer, and the first side is a side along which electrons migrate out of the light-emitting layer.

In another embodiment of the present disclosure, a material of the passivation layer is at least one of Si₃N₄, SiO₂, or Al₂O₃.

In another embodiment of the present disclosure, a material of a substrate of the micro-LED chip is selected from a group comprising: silicon (Si), silicon dioxide (SiO₂), silicon nitride (Si₃N₄), silicon carbide (SiC), gallium nitride (GaN), glass, aluminum nitride (AlN), sapphire (α-Al₂O₃), and germanium (Ge).

In another embodiment of the present disclosure, a material of the insulating layer is selected from a group comprising: silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof; and/or
a material of the metal layer is selected from a group comprising: aluminum (Al), copper (Cu), tungsten (W), silver (Ag), gold (Au), nickel (Ni), platinum (Pt), tantalum (Ta), and molybdenum (Mo).

In another embodiment of the present disclosure, the through-hole contact portions include a first through-hole contact portion and a second through-hole contact portion, and the insulating layers include a first insulating layer and a second insulating layer, and the micro-LED chip includes an upper stacked layer and a lower stacked layer, where the upper stacked layer includes the first insulating layer, the light-emitting mesa, and the first through-hole contact portion, and the lower stacked layer includes the second insulating layer, the second through-hole contact portion, and the drive circuit, where the lower stacked layer is jointed with the upper stacked layer through hybrid bonding, such that the first through-hole contact portion is bonded with the second through-hole contact portion, and the first insulating layer is bonded with the second insulating layer.

In the third aspect of the present disclosure, the aforementioned task is solved by a method for forming a light-emitting mesa, the method includes:
providing a temporary substrate;
forming an epitaxial layer on the temporary substrate, and the epitaxial layers include a second epitaxial layer in contact with the temporary substrate, a light-emitting layer arranged on the second epitaxial layer, and a first epitaxial layer arranged on the light-emitting layer;
forming a transparent conductive layer on the first epitaxial layer;
etching the transparent conductive layer in a first etching step to expose the first epitaxial layer, where the first epitaxial layer is not etched in the first etching step; and
etching the first epitaxial layer, the light-emitting layer, and the second epitaxial layer in a second etching step after the first etching step to form an inclined surface at a side surface of the light-emitting mesa, where an inclination angle of the inclined surface is 55° to 75°.

In one embodiment of the present disclosure, the second etching step includes:
coating a photoresist over the transparent conductive layer and the first epitaxial layer that is exposed;
exposing the photoresist to form an exposed portion at a circumference of the transparent conductive layer;
baking the photoresist to generate a photoresist collapse at the exposed portion;
developing and rinsing the photoresist to pattern the photoresist; and
etching the first epitaxial layer, the light-emitting layer, and the second epitaxial layer through the photoresist that is patterned to form the light-emitting mesa.

In another embodiment of the present disclosure, a baking temperature of the baking is 120° C. to 140° C., and a baking time of the baking is 8 minutes to 12 minutes.

In another embodiment of the present disclosure, the etching includes one or more of following items: chemical wet etching, ion beam etching, and reactive ion etching.

In another embodiment of the present disclosure, etching the first epitaxial layer, the light-emitting layer, and the second epitaxial layer through the patterned photoresist that is patterned to form the light-emitting mesa includes:
etching through the first epitaxial layer to expose the light-emitting layer;
etching through the light-emitting layer to expose the second epitaxial layer; and
etching through merely a part of the second epitaxial layer.

In another embodiment of the present disclosure, the method further includes following step:
forming a marking layer located between the temporary substrate and the epitaxial layer.

In another embodiment of the present disclosure, the method further includes following step:
removing the temporary substrate by debonding or grinding.

The present disclosure has at least the following technical effects:

(1) Through research, the inventors discovered that when the side surface inclination angle α of the light-emitting mesa is of 55° to 75°, particularly 60° to 70°, a good aperture ratio can be obtained. The principle on which it is based is as follows. Through research, the inventors discovered that when the upper side area of an upside-down arranged trapezoidal light-emitting mesa is fixed, its aperture ratio (the aperture ratio refers to the ratio of the actual light-emitting area to the total chip area) depends on the side surface inclination angle α, that is to say, the aperture area, i.e. the lower side area depends on the side surface inclination angle α (0<α<90°), the smaller the side surface inclination angle α, the larger the aperture area, and conversely, the larger the side surface inclination angle α, the smaller the aperture area, i.e., the it is closer to the upper side area, and when α=90°, the lower side area equals the upper side area, and the aperture area is the smallest. However, the side surface inclination angle α cannot be infinitely small, and when the side surface inclination angle α is too small, it not only imposes high requirements on the process, but also the ratio between the first and second epitaxial layers and the light-emitting layer will also be out of balance, and the luminous efficiency is affected. The inventors also discovered that when the side surface inclination angle α is of 55° to 75°, particularly 60° to 70°, the best aperture ratio and best luminous efficiency can be achieved, at the same time, this angle can be achieved through step-by-step etching, where the step-by-step etching means that the transparent conductive layer and other layers are etched in different steps.

(2) Through research, the inventors discovered that the main reason for the low aperture ratio in current micro-LEDs is that in the wet etching process, the transparent conductive layer and the epitaxial layer of the light-emitting mesa have different etching rates due to different materials, making it difficult to control the etching size and angle. In view of this, the inventors, by etching the transparent conductive layer and the epitaxial layer below it in two separate etching steps respectively, can avoid the disadvantages of uncontrollable etching rate and angle faced when etching the two in one step, and instead, the etching size and angle of the transparent conductive layer and the epitaxial layer can be well controlled in two steps respectively, so that a good inclination angle is achieved, i.e., an inclination angle of 55° to 75°, particularly 60° to 70° is achieved. This inclination angle is difficult to achieve in the case of unseparated etching.

(3) The present disclosure by continuing to bake the photoresist (e.g., 130° C. for 10 minutes) after exposing the photoresist on the light-emitting mesa, it can cause the photoresist to collapse near the exposed portion of the photoresist, and thus the verticality of the patterned edge of the photoresist is decreased, so that the inclination angle of the etched light-emitting mesa is reduced.

### BRIEF DESCRIPTION OF THE DRAWINGS

The present disclosure is further explained below with reference to the accompanying drawings in conjunction with specific implementation methods.

FIG. 1 illustrates a first embodiment of the light-emitting mesa according to the present disclosure;

FIG. 2 illustrates a second embodiment of the light-emitting mesa according to the present disclosure;

FIG. 3 illustrates a schematic diagram of a micro-LED chip having the light-emitting mesa according to the present disclosure; and

FIGS. 4A-4G illustrate a method for forming the light-emitting mesa according to the present disclosure.

### DESCRIPTION OF THE EMBODIMENTS

It should be noted that various components in the accompanying drawings may be exaggerated for the purpose of illustrative illustration and are not necessarily true to scale. In the accompanying drawings, components that are identical or functionally identical are provided with the same accompanying drawing reference signs.

In the present disclosure, unless otherwise specified, the words “arranged on”, “arranged above” and “arranged over” do not exclude the existence of intermediates between the two. Furthermore, “arranged on or above” merely indicates the relative positional relationship between the two components, but under certain circumstances, such as when the product direction is reversed, it can be converted to “arranged under or below”, and vice versa.

In the present disclosure, the embodiments are merely intended to illustrate the scheme of the present disclosure and should not be construed as limiting.

In the present disclosure, the quantifiers “a” and “one” do not exclude scenarios with a plurality of elements, unless otherwise specified.

In the present disclosure, the term “connect” may refer to either the two being directly connected or the two being indirectly connected through an intermediate component.

In the present disclosure, the term “configure” refers to the setting of the shape, structure, material, and/or function of a target object to achieve a desired technical effect, “configure” includes various alternative technical means to achieve this technical effect, and these technical means become apparent under the teachings of the present disclosure.

It should also be noted herein that in embodiments of the present disclosure, merely a portion of the components or assemblies may be shown for the sake of clarity and simplicity, but those ordinary skilled in the art will be able to understand that the required components or assemblies may be added as needed according to specific scenarios in light of the teachings of the present disclosure. Furthermore, features in different embodiments of the present disclosure may be combined with each other unless otherwise indicated. For example, a feature in the second embodiment may be substituted for a corresponding or functionally identical or similar feature in the first embodiment, and the resulting embodiment also falls within the scope of the disclosure or the scope of the record of the present application.

It should also be noted that, within the scope of the present disclosure, the terms “the same”, “equal”, “equal to”, etc. do not mean that the two numerical values are absolutely equal, but rather allow for a certain reasonable error, that is to say, the terms also cover “substantially the same” , “substantially equal” and “substantially equal to”. By analogy, in the present disclosure, the terms “perpendicular to”, “parallel to”, etc., which indicate direction, also cover the meaning of “substantially perpendicular to”, “substantially parallel to”.

In the present disclosure, the term “configure” refers to the setting of the shape, structure, material, and/or function of a target object to achieve a desired technical effect, “configure” includes various alternative technical means to achieve this technical effect, and these technical means become apparent under the teachings of the present disclosure.

In the present disclosure, the term “inclination angle of the light-emitting mesa” refers to the angle between the side surface of the light-emitting mesa and the bottom surface (e.g., the horizontal direction) of the light-emitting mesa. If the inclination angle of the side surface of each layer of the light-emitting mesa is the same, then this inclination angle is the inclination angle of each layer. If the inclination angle of the side surface of each layer is different, then this inclination angle is the average angular value over the total thickness, i.e. the sum of all layer thicknesses multiplied by the thicknesses and divided by the total thickness.

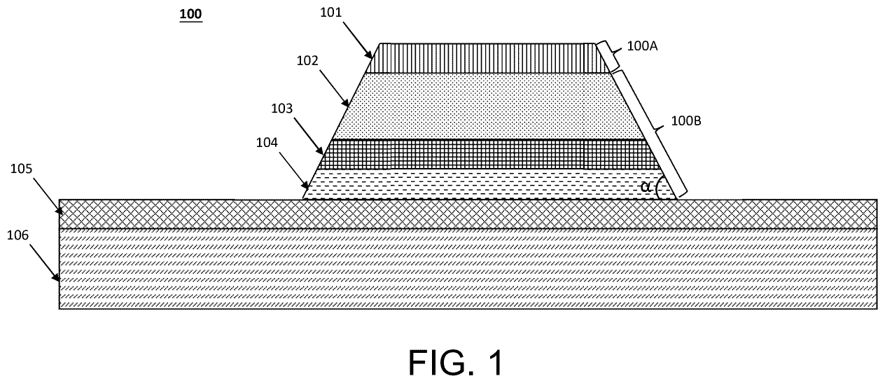

FIG. 1 illustrates a first embodiment of the light-emitting mesa 100 according to the present disclosure.

As shown in FIG. 1, the light-emitting mesa 100 according to the present disclosure includes, from top to bottom, a transparent conductive layer 101, a first epitaxial layer 102, a light-emitting layer 103, and a second epitaxial layer 104. Optionally, a marking layer 105 and a temporary substrate 106 are optionally arranged below the light-emitting mesa 100. Herein, the transparent conductive layer 101 is located at the uppermost side of the light-emitting mesa 100, but due to this light-emitting mesa 100 being an upside-down arranged trapezoidal structure, it actually corresponds to the bottom of the light-emitting mesa 100, i.e., facing away from the light extraction side; the second epitaxial layer 104 is located at the lowest side of the light-emitting mesa 100, but due to this light-emitting mesa 100 being an upside-down arranged trapezoidal structure, it actually corresponds to the top of the light-emitting mesa 100, i.e., facing the light extraction side. In the present disclosure, the term “light extraction side” refers to the side from which light emitted by the light-emitting mesa leaves the micro-LED, for example, the “light extraction side” may correspond to the side where the microlens of the micro-LED are located. As can be seen from FIG. 1, the side surface inclination angle of the light-emitting mesa 100 is α, the side surface inclination angle α is of 55° to 75°, particularly 60° to 70°, and thus a good aperture ratio for the micro-LED chip can be obtained.

Through research, the inventors discovered that when the upper side area of an upside-down arranged trapezoidal light-emitting mesa is fixed, its aperture ratio (the aperture ratio refers to the ratio of the actual light-emitting area to the total chip area) depends on the side surface inclination angle α, that is to say, the aperture area, i.e. the lower side area depends on the side surface inclination angle α (0<α<90°), the smaller the side surface inclination angle α, the larger the aperture area, and conversely, the larger the side surface inclination angle α, the smaller the aperture area, i.e., the it is closer to the upper side area, and when α=90°, the lower side area equals the upper side area, and the aperture area is the smallest. However, the side surface inclination angle α cannot be infinitely small, when the side surface inclination angle α is too small, it not only imposes high requirements on the process, but also the ratio between the first epitaxial layer 102, the second epitaxial layer 104 and the light-emitting layer 103 will also be out of balance, and the luminous efficiency is affected. The inventors also discovered that when the side surface inclination angle α is of 55° to 75°, particularly 60° to 70°, the best aperture ratio and best luminous efficiency can be achieved, at the same time, this angle can be achieved through step-by-step etching, and the step-by-step etching means that the transparent conductive layer and other layers are etched in different steps. Step-by-step etching can achieve the aforementioned optimal side surface inclination angle α, this is because the materials of the first epitaxial layer 102 and the second epitaxial layer 104 are the same, such as they both are of gallium nitride or gallium arsenide, while the material of the light-emitting layer 103 is basically the same as the first epitaxial layer 102 and the second epitaxial layer 104 (e.g., gallium nitride or gallium arsenide doped with a small amount of elements, such as indium, aluminum, etc.), therefore, the light-emitting layer 103 can be etched in the same etching step with the first epitaxial layer 102 and the second epitaxial layer 104, even if the material of the light-emitting layer 103 is different (e.g., aluminum gallium indium phosphide (AlGaInP)), but a thickness of the light-emitting layer 103 is relatively low compared to the first epitaxial layer 102 and the second epitaxial layer 104 (e.g., one-tenth to one-several-tenths), and its influence on the side surface inclination angle α is limited, therefore, the light-emitting layer 103 can be etched in the same etching step with the first epitaxial layer 102 and the second epitaxial layer 104. The material of the transparent conductive layer 101 is different from the material of the first epitaxial layer 102 and the second epitaxial layer 104, and if it is etched in the same etching step, it is difficult to achieve the optimal side surface inclination angle α of 55° to 75°, particularly 60° to 70°, due to the difficulty in controlling the etching speed and size of different materials. Therefore, the inventors achieved the aforementioned optimal side surface inclination angle α by step-by-step etching the transparent conductive layer 101 and other epitaxial layers, and specifically, first in the first etching step, for example, wet etching is used to etch the transparent conductive layer with a first etchant, and then in the second etching step, the first epitaxial layer 102 and the second epitaxial layer 104 and the light-emitting layer 103 are etched with a second etchant to achieve the aforementioned side surface inclination angle α. The first and second etchants may be the same or different, but the etching time allows for more controllable etching morphology in separate etching steps, so that the aforementioned side surface inclination angle α is achieved.

The various components of the light-emitting mesa 100 according to the present disclosure are described below, respectively.

### Transparent Conductive Layer

The transparent conductive layer 101 is arranged on the side of the light-emitting mesa 100 facing away from the light extraction side, i.e., the side facing the drive circuit. The function of the transparent conductive layer 101 is to electrically connect the first epitaxial layer 102 in the light-emitting mesa 100 with the drive circuit, particularly the first electrode, such as the anode. The material of the transparent conductive layer 101 is, for example, metal oxide such as indium tin oxide ITO or zinc oxide ZnO, etc., its formation methods include, for example, physical vapor deposition (PVD), chemical vapor deposition (CVD), sol-gel method, solution coating method, etc. The thickness of the transparent conductive layer 101 is, for example, 1350 Å, and its width is, for example, 1.0 μm. In the present disclosure, when the transparent conductive layer 101 is formed over the first epitaxial layer 102, the transparent conductive layer 101 is first etched in a first etching step to form a first inclined edge 100A of the transparent conductive layer 101. Subsequently, in a second etching step, the first epitaxial layer 102, the light-emitting layer 103, and the second epitaxial layer 104 are etched to form a second inclined edge 100B of the entire light-emitting mesa 100. The inclination angle of the first inclined edge 100A may be equal to the inclination angle of the second inclined edge 100B, for example both within the range of 55° to 75°, particularly 60° to 70°. Alternatively, the inclination angle of the first inclined edge 100A may be larger, e.g., greater than 70°, particularly greater than 75°, while the second inclined edge 100B may be less than 75°, particularly less than 70°, due to the fact that the thickness of the transparent conductive layer 101 is significantly less than the sum of the thicknesses of the first epitaxial layer 102, the light-emitting layer 103, and the second epitaxial layer 104, therefore, the average of the inclination angle of the first inclined edge 100A and the second inclined edge 100B on the total height of the light-emitting mesa 100 can still fall within the range of 55° to 75°, particularly 60° to 70°. In another case, the first inclined edge 100A and the second inclined edge 100B are not equal to each other, but their inclination angles are both within the range of 55° to 75°, particularly 60° to 70°. Herein, “the inclination angle of the inclined edge” refers to the angle formed by the inclined edge and the bottom surface of the light-emitting mesa 100 from the cross-sectional view of the light-emitting mesa 100, and the direction of the bottom surface of the light-emitting mesa 100 may be characterized, for example, by the length extension direction of the second epitaxial layer 102. Furthermore, in the present embodiment, the end of the first inclined edge 100A and the end of the second inclined edge 100B are connected with each other, i.e., in a smooth transition. In other embodiments, the end of the first inclined edge 100A and the end of the second inclined edge 100B may also be in non-smooth transition, i.e., their adjacent ends in the horizontal direction have a certain distance between them, and the distance is less than or equal to 0.2 μm.

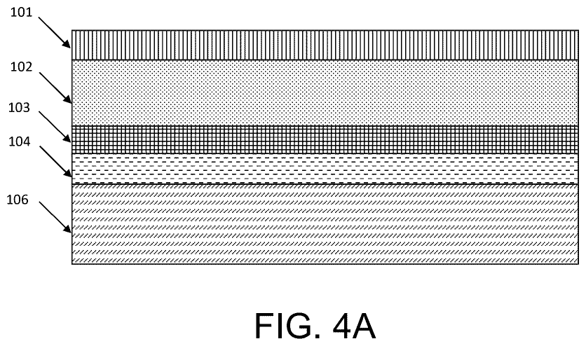

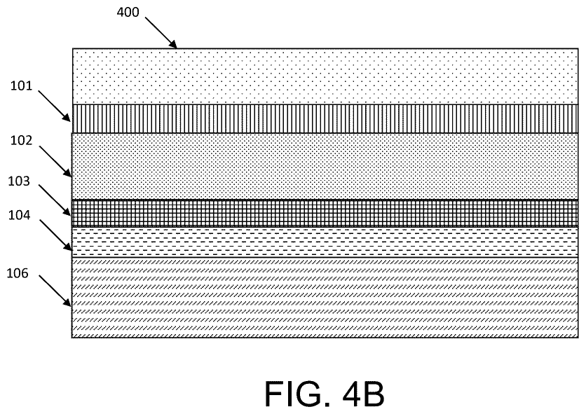

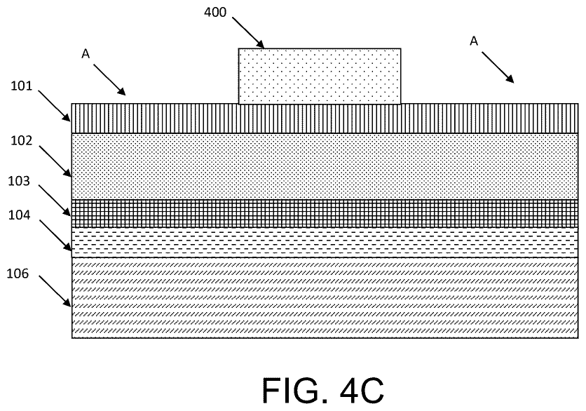

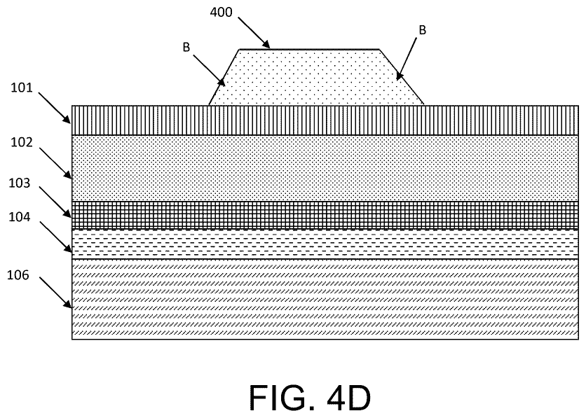

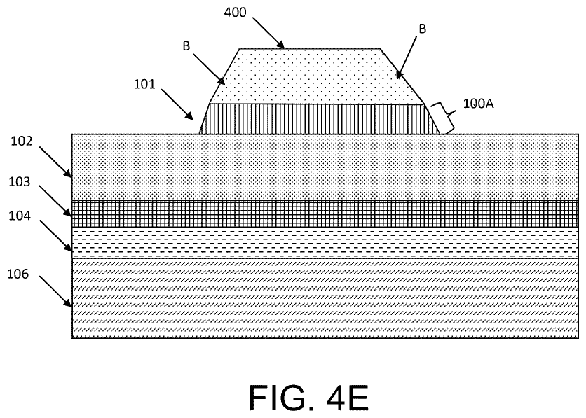

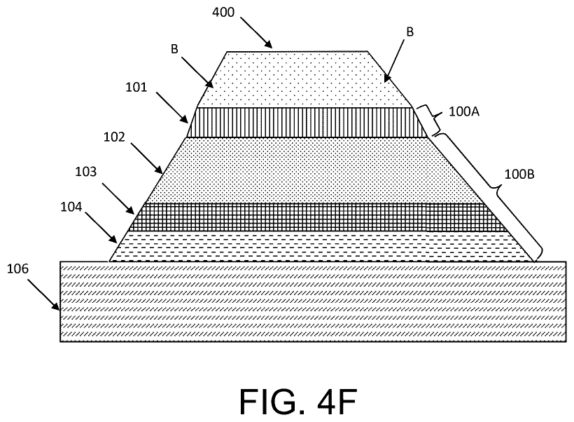

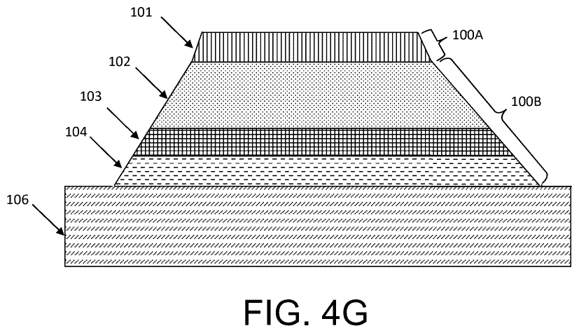

The etching methods for the transparent conductive layer 101 include but are not limited to: chemical wet etching, ion beam etching, and reactive ion etching. Furthermore, in one embodiment, after the photoresist is developed, the exposed portion of the photoresist is baked to generate photoresist collapse, and the photoresist collapse facilitates the formation of inclined edges in subsequent etching steps. For specific etching processes, reference may be made to FIGS. 4A-4G and its description.

### First Epitaxial Layer, Light-Emitting Layer, Second Epitaxial Layer

The first epitaxial layer 102 is arranged between the transparent conductive layer and the light-emitting layer 103. The light-emitting layer 103 is arranged between the first epitaxial layer 102 and the second epitaxial layer 104 and is configured to emit light. The second epitaxial layer 104 is arranged on the side of the light-emitting mesa 100 facing the light extraction side, the area of the second epitaxial layer 104 is greater than the area of the first epitaxial layer 102, and the side surface of the light-emitting mesa 100 has an inclined surface, the inclination angle α of the inclined surface is of 55° to 75°, preferably 60° to 70°.

In some embodiments, the light-emitting layer 103 is formed by a plurality of stacked quantum well layers, particularly superlattice-stacked quantum well layers. Preferably, the superlattice-stacked quantum well layers include a plurality of pairs of quantum well layers stacked with quantum barrier layers. In some embodiments, the first epitaxial layer 102 is a semiconductor material with a first conductivity type and includes a plurality of semiconductor layers. The main matrix material of the first epitaxial layer 102 may be, but is not limited to, composed of materials such as Ga, N, As, P, In, or Al, etc. Furthermore, the first epitaxial layer 102 may include, from top to bottom, but is not limited to, a waveguide layer, a confinement layer, a transition layer, and a window layer; furthermore, an ohmic contact layer may be formed below the window layer. In some embodiments, the second epitaxial layer 104 is a semiconductor material with a second conductivity type and includes a plurality of semiconductor layers. The main matrix material of the second epitaxial layer 104 may be, but is not limited to, composed of materials such as Ga, N, As, P, In, or Al, etc. Furthermore, the second epitaxial layer 104 may include, from top to bottom, but is not limited to, a confinement layer and a waveguide layer; furthermore, in some embodiments, an ohmic contact layer may be formed on the confinement layer. In one embodiment, the first conductivity type is different from the second conductivity type.

In one embodiment, the second epitaxial layer 104 is an N-type GaN layer or an N-type AlGaN layer, and the first epitaxial layer 102 is a P-type GaN layer or a P-type AlGaN layer, i.e. the material of the second epitaxial layer 104 is a material layer of a second conductivity type including at least two or more elements of Ga, N, As, Al, In, and P, and the first epitaxial layer 102 is a material layer of a first conductivity type including at least two or more elements of Ga, N, As, Al, In, and P. In one embodiment, the light-emitting layer 103 includes a multi-quantum-well layer and an electron barrier layer, and the multi-quantum-well layer is an InGaN/GaN multi-quantum-well layer, or an InGaN/AlGaN multi-quantum-well layer, or an InGaAs/AlGaAs multi-quantum-well layer. In another embodiment, the second epitaxial layer 104 may also be a P-type GaN layer or a P-type AlGaN layer, and the first epitaxial layer 102 is an N-type GaN layer or an N-type AlGaN layer.

In some embodiments, the light-emitting layer 103 includes at least one quantum well layer. The thickness of the quantum well layer is between 20 nm and 40 nm, for example, the thickness is 30 nm. In some embodiments, the material of the quantum well layer is GaInP/(AlₓGa1−x)_{y}In_{1-y}P, the range of x is 0.5 to 0.9, and the range of y is 0.3 to 0.5. For example, x is 0.8 and y is 0.5. In some embodiments, the relationship between x and y is that x is 1 to 2 times y. In some embodiments, the light-emitting layer 103 is a multi-quantum well (MQW).

In embodiments of the present disclosure, one of the first epitaxial layer 102 and the second epitaxial layer 104 is an N-type semiconductor layer, and the other is a P-type semiconductor layer. In some embodiments, the N-type semiconductor layer also includes a doped N-type contact layer and an N-type cladding layer. The material of the N-type cladding layer is AlₓIn₁₋ₓP, and the range of x is 0.1 to 0.5, for example, x is 0.5. Furthermore, in these embodiments, the thickness of the N-type cladding layer is no greater than 350 nm, for example, the thickness of the N-type cladding layer is 320 nm. The doping concentration of the N-type cladding layer is 5e¹⁷ cm⁻³ to 1e¹⁸ cm⁻³. In some embodiments, the N-type semiconductor layer also includes a doped N-type contact layer and an N-type cladding layer formed on the doped N-type contact layer. The doped N-type contact layer is configured to bond with the bonding layer. The material of the doped N-type contact layer is GaAs. In some embodiments, the thickness of the doped N-type contact layer is 10 nm to 30 nm. In some embodiments, the doping concentration of the doped N-type contact layer is 2e¹⁸ cm⁻³ to 1e¹⁹ cm⁻³. In some embodiments, the N-type semiconductor layer also includes an N-type spacer layer formed on the N-type cladding layer. The material of the N-type spacer layer is (AlₓGa1−x)_{y}In_{1-y}P, the range of x is 0.5 to 0.9, and the range of y is 0.1 to 0.5. For example, x is 0.8 and y is 0.5. In some embodiments, the relationship between x and y is that x is 1 to 2 times y. The thickness of the N-type spacer layer is 50 nm to 75 nm, for example 65 nm. In some embodiments, the P-type semiconductor layer includes a P-type cladding layer and a doped P-type contact layer. The P-type cladding layer is formed on the light-emitting layer 103, and the doped P-type contact layer is formed on the P-type cladding layer.

In some embodiments, the material of the P-type cladding layer is AlₓIn₁₋ₓP, and x is 0.3 to 0.5, for example, x is 0.5. In such embodiments, the thickness of the P-type cladding layer is no greater than 380 nm, for example, the thickness of the P-type cladding layer is 360 nm.

In some embodiments, the material of the doped P-type contact layer is GaAs. The thickness of the doped P-type contact layer is 10 nm to 30 nm, for example 20 nm.

In some embodiments, the P-type semiconductor layer also includes a P-type spacer layer formed below the P-type cladding layer, a first doped P-type transition layer formed on the P-type cladding layer, and a second doped P-type transition layer formed on the first doped P-type transition layer. In some embodiments, the material of the P-type spacer layer is (AlₓGa1−x)_{y}In_{1-y}P, the range of x is 0.5 to 0.9, and the range of y is 0.3 to 0.5. For example, x is 0.8 and y is 0.5. In some embodiments, the relationship between x and y is that x is 1 to 2 times y. The thickness of the P-type spacer layer is 50 nm to 75 nm, for example 65 nm.

In some embodiments, the material of the first doped P-type transition layer is (AlₓGa1−x)_{y}In_{1-y}P, the range of x is 0.1 to 0.3, and the range of y is 0.3 to 0.5. For example, x is 0.17 and y is 0.5. In some embodiments, the relationship between x and y is that y is 1 to 5 times x. In some implementations, the thickness of the first doped P-type transition layer is 20 nm to 40 nm, for example 30 nm.

In some embodiments, the material of the second doped P-type transition layer is AlₓGa₁₋ₓAs, and the range of x is 0.5 to 0.9, for example x is 0.6. In some embodiments, the thickness of the second doped P-type transition layer is 10 nm to 30 nm, for example 20 nm.

In some embodiments, the doping concentration of the second doped P-type transition layer is greater than the doping concentration of the first doped P-type transition layer. The doping concentration of the doped P-type contact layer is 1 to 10 times the doping concentration of the second doped P-type transition layer.

In some embodiments, the doping concentration of the doped P-type contact layer is greater than the doping concentration of the second doped P-type transition layer. Furthermore, in some embodiments, the doping concentration of the second doped P-type transition layer is 2 to 4 times the doping concentration of the first doped P-type transition layer.

For example, the doping concentration of the first doped P-type transition layer is greater than 1e¹⁸ cm⁻³, the doping concentration of the second doped P-type transition layer is in the range of 2e¹⁸ cm⁻³ to 4e¹⁸ cm⁻³, and the doping concentration of the doped P-type contact layer is greater than 5e¹⁸ cm⁻³.

In the present disclosure, the first epitaxial layer 102, the light-emitting layer 103, and the second epitaxial layer 104 are etched during the second etching step after their formation. That is, the transparent conductive layer 101 is first etched in the first etching step to form the first inclined edge 100A of the transparent conductive layer 101. Then, in the second etching step, the first epitaxial layer 102, the light-emitting layer 103, and the second epitaxial layer 104 are etched to form the second inclined edge 100B of the entire light-emitting mesa 100. The inclination angle of the first inclined edge 100A may be equal to the inclination angle of the second inclined edge 100B, for example, they both are within the range of 55° to 75°, particularly 60° to 70°. Alternatively, the inclination angle of the first inclined edge 100A may be larger, for example greater than 70°, particularly greater than 75°, while the inclination angle of the second inclined edge 100B may be less than 75°, particularly less than 70°. Since the thickness of the transparent conductive layer 101 is significantly less than the sum of the thicknesses of the first epitaxial layer 102, the light-emitting layer 103, and the second epitaxial layer 104 (e.g., 1/10th or less), the average value of the inclination angle of the first inclined edge 100A and the second inclined edge 100B on the total height of the light-emitting mesa 100 are primarily determined by the inclination angle of the second inclined edge 100B, i.e. it can still fall within the range of 55° to 75°, particularly 60° to 70°. In another case, the first inclined edge 100A and the second inclined edge 100B are not equal to each other, but their inclination angles are both within the range of 55° to 75°, particularly 60° to 70°. Herein, “the inclination angle of the inclined edge” refers to the angle formed by the inclined edge and the bottom surface of the light-emitting mesa 100 when seen from the cross-sectional view of the light-emitting mesa 100, and the direction of the bottom surface of the light-emitting mesa 100 may be characterized, for example, by the length extension direction of the second epitaxial layer 102. The side surface of the transparent conductive layer 101 has a first inclined edge 100A, and the side surfaces of the first epitaxial layer 102, the light-emitting layer 103, and the second epitaxial layer 104 have a second inclined edge 100B.

For example, the first inclined edge 100A of the transparent conductive layer 101 has a first inclination angle X, and the thickness of the transparent conductive layer 101 is d1, while the second inclined edge 100B of the first epitaxial layer 102, the light-emitting layer 103, and the second epitaxial layer 104 has a second inclination angle Y, and the first epitaxial layer 102, the light-emitting layer 103, and the second epitaxial layer 104 have a thickness d2. The average inclination angle d of the light-emitting mesa 100 over the entire thickness is:
d=(X*d1+Y*d2)/(d1+d2).

Herein, d falls within the range of 55° to 75°, particularly 60° to 70°. That is to say, even if the layers etched during different etching steps have different inclination angles, a good aperture ratio can still be ensured as long as the average inclination angle d is within the aforementioned range. For example, with X=85°, and Y=65°, since d1=d2/10, the average inclination angle d=66.8°.

Furthermore, in the present embodiment, the end of the first inclined edge 100A and the end of the second inclined edge 100B are connected with each other, i.e., in a smooth transition. In other embodiments, the end of the first inclined edge 100A and the end of the second inclined edge 100B may also be in non-smooth transition, i.e., their adjacent ends in the horizontal direction have a certain distance between them, and the distance is less than or equal to 0.2 μm.

The etching methods for the first epitaxial layer 102, the light-emitting layer 103, and the second epitaxial layer 104 include but are not limited to: chemical wet etching, ion beam etching, and reactive ion etching. Furthermore, in one embodiment, after the photoresist is developed, the exposed portion of the photoresist has been baked to generate photoresist collapse, and the photoresist collapse facilitates the formation of inclined edges in subsequent etching steps. For specific etching processes, reference may be made to FIGS. 4A-4G and its description.

As shown in FIG. 1, the light-emitting mesa 100 according to the present disclosure has a good side surface inclination angle, thus having a good aperture area. For example, the bottom width of the light-emitting mesa 100 can reach 1.4 to 1.7 μm, preferably 1.6 μm. The depth of the light-emitting mesa 100 can be 0.3 to 0.7 μm, preferably 0.4 to 0.6 μm.

Furthermore, FIG. 1 also illustrates a marking layer 105 and a temporary substrate 106. The marking layer 105 is arranged between the second epitaxial layer 104 and the temporary substrate 106. The marking layer 105 serves to mark the position of the second epitaxial layer 104 when removing the temporary substrate 106 to avoid damaging the second epitaxial layer 104. For example, the marking layer 105 may serve as an etching buffer layer or a grinding buffer layer, with a thickness of, for instance, 5000 Å. The temporary substrate 106 is used for the epitaxial growth of the epitaxial layers, i.e. the first epitaxial layer 102, the light-emitting layer 103, and the second epitaxial layer 104, and for supporting the epitaxial layers and the transparent conductive layer 101 in subsequent processes. The thickness of the temporary substrate 106 may be, for example, 600 μm to 1000 μm, preferably 800 μm. After the relevant processes are completed, the temporary substrate 106 and the marking layer 105 can be removed, for example, the temporary substrate 106 can be removed through debonding and grinding, such as CMP, and the marking layer 105 can be removed through etching or grinding, such as CMP.

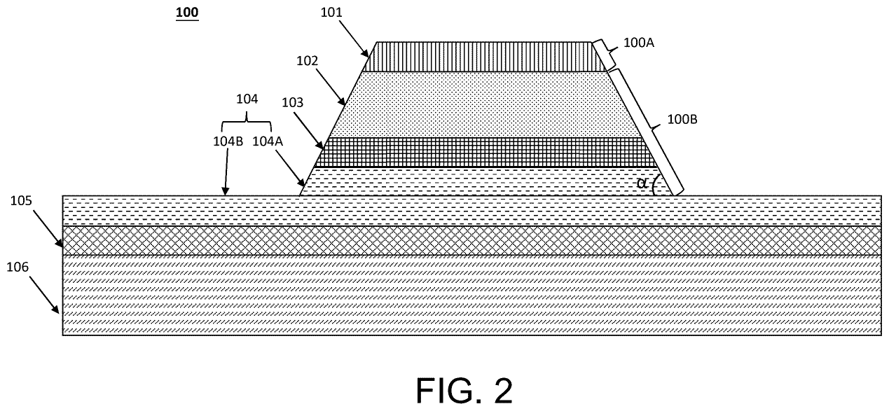

FIG. 2 illustrates a second embodiment of the light-emitting mesa 100 according to the present disclosure.

The second embodiment of the light-emitting mesa 100 shown in FIG. 2 is substantially the same as the first embodiment of the light-emitting mesa 100 shown in FIG. 1, and the main difference lies in that, in the second embodiment of FIG. 2, the second epitaxial layer 104 of the light-emitting mesa 100 includes two portions, i.e. a step portion 104A and a base portion 104B. The step portion 104A is in electrical contact with the light-emitting layer 103, and the base portion 104B extends from the step portion 104A to two sides, i.e. extend beyond the step portion 104A. In one embodiment, the thickness of the step portion 104A is 2000 Å, and the thickness of the base portion 104B is 1000 Å. Herein, the second inclined edge 100B includes the inclined surfaces of the first epitaxial layer 102, the light-emitting layer 103, and the step portion 104A. The base portion 104B may extend to adjacent light-emitting mesas 100 and be continuously connected with its base portion 104B. In this embodiment, not only the thickness of the second epitaxial layer 104 can be increased, but also its surface area facing the light-emitting side is not limited by the slope, but can extend to adjacent light-emitting mesas 100, so that the luminous efficiency is improved.

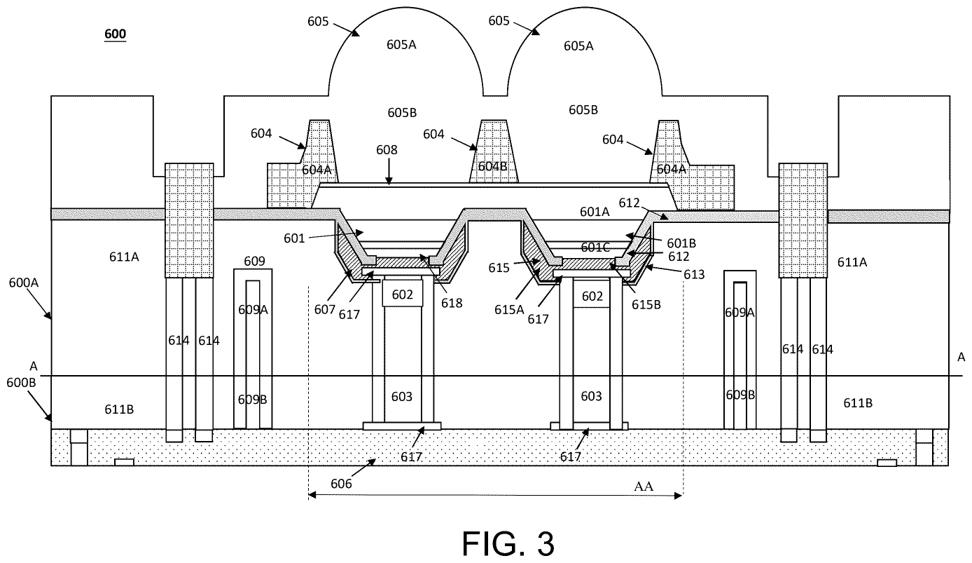

FIG. 3 illustrates a schematic diagram of a micro-LED chip 600 having the light-emitting mesa according to the present disclosure. In this application scenario, the light-emitting mesa or epitaxial layer of the micro-LED chip 600 has an upside-down arranged trapezoidal structure, i.e. the light-emitting mesa of the micro-LED chip 600 is a structure with a larger upper surface and a smaller lower surface, and the inclination angle of the light-emitting mesa is 55° to 75°, preferably 60° to 70°.

The various components of the micro-LED chip 600 are described in detail below.

As shown in FIG. 3, the micro-LED chip 600 according to the present disclosure includes an upper stacked layer 600A and a lower stacked layer 600B, and the upper stacked layer 600A and the lower stacked layer 600B are formed into a complete micro-LED chip 600 through hybrid bonding at interface A-A. The structure and components of the upper stacked layer 600A and the lower stacked layer 600B are described in detail below.

### Upper Stacked Layer

The upper stacked layer 600A includes a first insulating layer 611A, a light-emitting mesa 601, a transparent conductive layer 608, a first electrode 604 (cathode), a first through-hole contact portion 602, a second electrode 610 (anode), a first bonding mark 609A, and microlens 605. The various components are described below, respectively.

The first insulating layer 611A is configured to accommodate at least a part of the light-emitting mesa 601 and provide electrical insulation for the light-emitting mesa 601. Herein, the first insulating layer 611A has a recess 607 configured to accommodate the light-emitting layer and the second epitaxial layer of the light-emitting mesa 601, as well as the ancillary structures. For a detailed description of the light-emitting mesa 601 and its ancillary structures (such as the passivation layer 612, the reflective mirror layer 615, etc.), reference may be made to the light-emitting mesa 601 and description thereof. Herein, it should be noted that the recess 607 may be formed after the light-emitting mesa 601, i.e. the light-emitting mesa 601 and its ancillary structures are first formed on a temporary substrate, then the first insulating layer 611A surrounding them is formed on the light-emitting mesa and its ancillary structures. The material of the first insulating layer 611A may be, for example, silicon dioxide, silicon nitride, high-k dielectric materials (such as hafnium oxide, aluminum oxide, etc.), and so on. Methods for forming the first insulating layer 611A may include thermal oxidation, chemical vapor deposition (CVD), etc. The thickness of the first insulating layer 611A is, for example, 1 μm to 3 μm, preferably 2 μm, and more preferably 0.6 μm to 1.4 μm. Furthermore, the first insulating layer 611A may be planarized at interface A-A (e.g., through chemical mechanical polishing CMP) to facilitate hybrid bonding with the second insulating layer 611B.

The first insulating layer 611A is transparent to light emitted from the light-emitting mesa 601. In some embodiments, the first insulating layer 611A is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the first insulating layer 611A may facilitate the passage of light emitted from the light-emitting mesa 601. In some embodiments, the first insulating layer 611A may include a plurality of portions, such as three embedded dielectric portions and two adhering dielectric portions. The embedded dielectric portions refer to the dielectric layers surrounding each light-emitting diode structure; while the adhering dielectric portions refer to the dielectric layers between two light-emitting diode structures. The embedded dielectric portions and the adhering dielectric portions may have the same or different compositions.

Light-emitting mesa 601 is configured to emit light, and the top surface area of the light-emitting mesa 601 is greater than the bottom surface area of the light-emitting mesa 601, the light-emitting mesa 601 is in the shape of an upside-down arranged trapezoid. The inclination angle of light-emitting mesa 601 according to the present disclosure is 55° to 75°, preferably 60° to 70°. The light-emitting mesa 601 includes a first epitaxial layer 601A (corresponding to the second epitaxial layer 104 in FIG. 1), a light-emitting layer 601B (corresponding to the light-emitting layer 103 in FIG. 1), and a second epitaxial layer 601C (corresponding to the first epitaxial layer 102 in FIG. 1), and the first epitaxial layer 601A is arranged on the top surface of the light-emitting mesa 100, i.e., the side facing the light extraction surface; the light-emitting layer 601B is arranged in the recess 607 and arranged between the first epitaxial layer 601A and the second epitaxial layer 601C; and the second epitaxial layer 601C is arranged on the bottom of the light-emitting mesa 601, i.e., the side facing the drive circuit 606. The light-emitting layer 601B may include, for example, a multi-quantum-well layer and an electron barrier layer. In one embodiment of the present disclosure, the first epitaxial layer 601A is an N-type GaN layer or an N-type AlGaN layer, and the second epitaxial layer 601C is a P-type GaN layer or a P-type AlGaN layer, i.e., the material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P. The multi-quantum-well layer is an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present disclosure, the first epitaxial layer may also be a P-type GaN layer or a P-type AlGaN layer, and the second epitaxial layer is an N-type GaN layer or an N-type AlGaN layer. The top width of the light-emitting mesa 601 is, for example, 0.5 μm to 3 μm, preferably 1.0 μm to 2.0 μm. The thickness of the first epitaxial layer 601A is, for example, 4000 Å to 5000 Å, the thickness of the light-emitting layer 601B is, for example, 3500 Å to 4000 Å, and the thickness of the second epitaxial layer 601C is, for example, 2500 Å to 3500 Å. 1 angstrom (Å)=10\hat{ }(−10) m. From FIG. 3, it can also be seen that the first epitaxial layer 601A is located outside the recess 607, while the light-emitting layer 601B and the second epitaxial layer 601C are located within the recess 607, therefore, the surface area of the first epitaxial layer 601A is not limited by the aperture area of the recess 607 but can be significantly greater than the aperture area of the recess 607, thereby significantly increasing the area and thickness of the first epitaxial layer 601A; furthermore, due to the fact that merely the light-emitting layer 601B and the second epitaxial layer 601C need to be accommodated in the recess 607, these two layers have a larger area and thickness compared to the structure that requires accommodating three layers in the prior art, and thus the area and thickness of the epitaxial layer 601 are better increased, and the light output is improved. It can also be seen herein that the first epitaxial layer 601A passes through the first electrode 604 (herein is the cathode) from below the first electrode 604, so that the first epitaxial layers 601A of adjacent light-emitting mesas 601 can be connected to each other, and thus in the case of a common-cathode structure (i.e., where the first epitaxial layers of all micro-LEDs in the same array are connected to a common cathode), which can significantly enhance the conductivity between the cathode 604 and the first epitaxial layers 601A compared to the case where it is connected to the cathode 604 solely by the transparent conductive layer 608 covering it, the conductivity between the cathode 604 and the first epitaxial layer 601A can be significantly enhanced, thereby increasing its power supply. Furthermore, the contact cross-section between the first epitaxial layer 601A and the cathode 604 at the edge is partially planar and partially inclined surface. The inclined surface increases the contact area between the first epitaxial layer 601A and the cathode 604 compared to a vertical surface, and thus the conductivity is increased.

The light-emitting mesa 601 also includes ancillary structures such as passivation layers 612 and 613, a reflective mirror layer 615, and a bottom transparent conductive layer 618 (corresponding to the transparent conductive layer 101 in FIG. 1), etc. The passivation layer 612 is arranged between the light-emitting mesa 601 and the reflective mirror layer 615, and optionally extends on the upper surface of the first insulating layer 611A, and the passivation layer 613 is arranged between the inner wall of the recess 607 and the reflective mirror layer 615, and optionally extends on the upper surface of the first insulating layer 611A. In another embodiment, merely one of the passivation layers 612 and 613 extends on the upper surface of the first insulating layer 611A, or neither of them extends over the upper surface of the first insulating layer 611A, instead, they extend merely until to the upper surface of the first insulating layer 611A, while the upper surface of the first insulating layer 611A is covered by another insulating layer or dielectric layer. The function of passivation layers 612 and 613 is not merely to reduce current leakage at the sidewalls, but also to passivate sidewall defects and block damage to the light-emitting mesa caused by water, oxygen, etc. during operation, and they can also prevent metal diffusion from the reflective mirror layer 615, the cathode 604 etc. to the first insulating layer 611 or the light-emitting mesa 601. The passivation layers 612 and 613 may be formed by depositing SiO₂ material using a CVD process, and also may be formed by depositing Al₂O₃ material using an ALD (Atomic Layer Deposition) process. The bottom transparent conductive layer 618 is arranged between the second epitaxial layer 601C and the reflective mirror layer 615. The bottom transparent conductive layer 618 is configured to electrically connect the second epitaxial layer 601C of the light-emitting mesa 601 to the reflective mirror layer 615 and further to the through-hole contact portion 602. The material of the bottom transparent conductive layer 618 is, for example, metal oxide such as indium tin oxide ITO or zinc oxide ZnO, etc., its formation methods include, for example, physical vapor deposition (PVD), chemical vapor deposition (CVD), sol-gel method, solution coating method, etc.

The reflective mirror layer 615 is configured to reflect light from the light-emitting mesa 601 upward. For this purpose, the reflective mirror layer 615 has an inclined surface on the side facing the light-emitting mesa 601, the inclination angle of this surface is, for example, the same as the inclination angle of the light-emitting mesa 601, of 10° to 85°, preferably 30° to 70°, particularly 35° to 50°.

Herein, the reflective mirror layer 615 includes a side reflective mirror layer 615A and a bottom reflective mirror layer 615B. The side reflective mirror layer 615A covers at least a part of the side surface of the light-emitting mesa 601. Both the side reflective mirror layer 615A and the bottom reflective mirror layer 615B are configured to reflect light from the light-emitting mesa 601 upward, while the bottom reflective mirror layer 615B is also configured to electrically connect the bottom transparent conductive layer 618 with the first through-hole contact portion 602. In the present embodiment, the side reflective mirror layer 615A covers a part of the side surface of the light-emitting mesa 601 within the recess 607, and the side reflective mirror layer 615A is formed between the passivation layer 612 and the inner wall of the recess 607 of the insulating layer. Due to the presence of the passivation layer 612, the side reflective mirror layer 615A may or may not have an atomic layer deposition layer on the side facing the light-emitting mesa 601. In the case of having an atomic layer deposition layer, it is possible to further prevent the metal in the reflective mirror layer 615 from penetrating into the light-emitting mesa 601 through the passivation layer 612. The side reflective mirror layer 615A has an inclined surface on the side facing the light-emitting mesa 601 to reflect light from the light-emitting mesa upward, the inclination angle of the inclined surface is, for example, the same as the inclination angle of the light-emitting mesa 601, of 10° to 85°, preferably 30° to 70°, and especially 35° to 50°. The bottom reflective mirror layer 615B covers at least a part of the bottom surface of the light-emitting mesa 601. In the present embodiment, the bottom reflective mirror layer 615B covers the bottom transparent conductive layer 618 of the light-emitting mesa 601. The bottom reflective mirror layer 615B has an atomic layer deposition layer on the side facing the light-emitting mesa 601. The atomic layer deposition layer can block metal from the reflective metal layer to prevent its diffusion while substantially not affecting light reflection. For the specific structure of the reflective mirror layer 615, reference may be made to FIGS. 1 and 2 and their descriptions.

The reflective mirror layer 615 may include, from top to bottom (i.e., from the side facing the light-emitting mesa 601 to the side facing away from the light-emitting mesa 601), for example, an atomic layer deposition layer, a reflective metal layer, a first barrier layer, and a second barrier layer, the upper side of the reflective mirror layer faces the light-emitting mesa or epitaxial layer of the micro-LED, and the lower side of the reflective mirror layer faces away from the light-emitting mesa or epitaxial layer of the micro-LED or faces the bottom transparent conductive layer.

For example, the stacked layer structure of the reflective mirror layer 615 is as follows (in an order from close to the light-emitting mesa 601 to far away from the light-emitting mesa 601):
An atomic layer deposition layer, the material of which is nickel, the thickness is 5 angstroms;
A reflective metal layer, the material of which is silver, the thickness is 1000 angstroms;
A first barrier sublayer and a second barrier sublayer, the material of which is titanium and platinum, the thickness is 200 angstroms and 500 angstroms, respectively;
A second barrier layer, the material of which is titanium, the thickness is 200 angstroms.
Furthermore, the number of the first barrier layer is 3.

The reflective mirror layer 615 can be formed, for example, through methods such as evaporation, sputtering, or chemical vapor deposition (CVD), etc., the atomic layer deposition layer of the reflective mirror layer 615 is formed by atomic layer deposition. The thickness of the passivation layer 612 between the reflective mirror layer 615 and the light-emitting mesa 601 is 800 angstroms to 2000 angstroms, preferably 600 angstroms to 1600 angstroms. The thickness of the passivation layer 613 between the reflective mirror layer 615 and the inner wall of the recess 607 is 200 angstroms to 800 angstroms, preferably 300 angstroms to 600 angstroms.

In the present disclosure, the bottom transparent conductive layer 618 (corresponding to the transparent conductive layer 101 in FIG. 1) and the first epitaxial layer 601A (corresponding to the second epitaxial layer 104 in FIG. 1), the light-emitting layer 601B (corresponding to the light-emitting layer 103 in FIG. 1), and the second epitaxial layer 601C (corresponding to the first epitaxial layer 102 in FIG. 1) are etched with inclined side surfaces during different etching steps. For example, in a first etching step, the top transparent conductive layer 618 is first etched to form a first inclined edge of the transparent conductive layer 618. Then, in a second etching step, the first epitaxial layer 601A, the light-emitting layer 601B, and the second epitaxial layer 601C are etched to form a second inclined edge of the entire light-emitting mesa 601. The inclination angle of the first inclined edge may be equal to the inclination angle of the second inclined edge, for example both within the range of 55° to 75°, particularly 60° to 70°. Alternatively, the inclination angle of the first inclined edge may be larger, e.g., greater than 70°, particularly greater than 75°, while the second inclined edge may be less than 75°, particularly less than 70°, due to the fact that the thickness of the top transparent conductive layer 618 is significantly less than the sum of the thicknesses of the first epitaxial layer 601A, the light-emitting layer 601B, and the second epitaxial layer 601C, therefore, the average of the inclination angle of the first inclined edge and the second inclined edge on the total height of the light-emitting mesa can still fall within the range of 55° to 75°, particularly 60° to 70°. In another case, the first inclined edge and the second inclined edge are not equal to each other, but their inclination angles are both within the range of 55° to 75°, particularly 60° to 70°. The above optimized inclination angle configuration increases the surface area of the first epitaxial layer 601A of the micro-LED chip, i.e. enhances the aperture ratio, meanwhile it can also increase the width and area of the light-emitting layer 601B and the second epitaxial layer 601C, thereby improving the overall light output.

The top transparent conductive layer 608 is arranged on the first epitaxial layer 601A and electrically connects the first electrode 604 (cathode) with the first epitaxial layer 601A. Herein, the top transparent conductive layer 608 extends on the first epitaxial layer 601A and fully covers the first epitaxial layer 601A, thereby providing more uniform power supply for the first epitaxial layer 601A. In other embodiments, the top transparent conductive layer 608 may merely partially cover the first epitaxial layer 601A. Furthermore, the top transparent conductive layer 608 extends below the first electrode 604, which is the cathode in this case, such that the transparent conductive layer 608 extends continuously on the first epitaxial layer 601A of adjacent light-emitting mesas 601, so that the coverage area for the first epitaxial layer 601A is increased. The material of the top transparent conductive layer 608 is, for example, metal oxide such as indium tin oxide ITO or zinc oxide ZnO, etc. Its formation methods, for example, include physical vapor deposition (PVD), chemical vapor deposition (CVD), sol-gel method, solution coating method, etc.

The first electrode 604, herein is the cathode, which is arranged to surround the light-emitting mesa 601. The cathode 604 and its connecting components may be made of materials such as metals (such as silver, gold, or platinum), graphene, ITO, aluminum doped zinc oxide (AZO) or fluorine doped tin oxide (FTO), or any combination of the above materials. In yet another embodiment of the present disclosure, the cathode 604 and its connecting components may be made of non-transparent or transparent conductive materials, such as indium tin oxide (ITO). In a preferred embodiment, the cathode 604 is made of a reflective metal, so that the cathode 604 can optically isolate adjacent light-emitting mesas 601 from each other and meanwhile also can reflect light from the light-emitting mesas 601, for example, reflecting the light upward to the microlens 605, thereby increasing light output. In another embodiment, a reflective layer, such as a silver layer, may be coated onto the surface of the cathode 604 to provide reflective capability. Herein, the surface of the cathode 604 facing the light-emitting mesa 601 is an inclined surface, and it is inclined towards two sides (i.e. inclined from the bottom surface towards two sides), so that the light falling on it can be reflected upward, i.e. towards the light extraction side. Furthermore, the cathode 604 may be divided into an edge cathode 604A and a central cathode 604B, the edge cathode 604A is arranged between the second electrode 610 (herein is the anode) and the outermost light-emitting mesa 601, a part of the edge cathode 604A is arranged on the passivation layer 612, and another portion is arranged on the transparent conductive layer 608, while the central cathode 604B is arranged between adjacent light-emitting mesas 601, the central cathode 604B is arranged on the transparent conductive layer 608. In this way, the edge cathode 604A can completely cover the side surface of the first epitaxial layer 601A and be in electrical contact with it, thereby increasing the electrical contact area between the cathode 604 and the first epitaxial layer 601A.

The first through-hole contact portion 602 is electrically connected with the bottom of the light-emitting mesa 601 and passes through the first insulating layer 611A. The first through-hole contact portion 602 is used for hybrid bonding with the second through-hole contact portion 603, and thereby electrically connecting the bottom of the light-emitting mesa 601, particularly the second epitaxial layer 601C to the second electrode 610 (herein is the anode). The first through-hole contact portion 602 is preferably a cylindrical through-hole, and the inner wall and/or central space is filled with a conductor, such as metallic copper. The diameter of the first through-hole contact portion 602 is of 0.3 μm to 2 μm, preferably 0.6 μm to 1.4 μm. The first through-hole contact portion 602 may be planarized at interface A-A (e.g., through chemical mechanical polishing CMP) to facilitate hybrid bonding with the second through-hole contact portion 603. Furthermore, in order to enhance the bonding strength and improve the conductivity between the first through-hole contact portion 602 and the second through-hole contact portion 603, a first interface metal layer may be arranged at the first aperture of the first through-hole contact portion 602, and the area of the first interface metal layer is greater than the area of the first aperture. Similarly, a second interface metal layer may be arranged at the second aperture of the second through-hole contact portion 603, and the area of the second interface metal layer is greater than the area of the second aperture. The areas of the first interface metal layer and the second interface metal layer may be equal, or the area of the first interface metal layer may be greater or less than the area of the second interface metal layer. After the first interface metal layer and the second interface metal layer 202 are bonded to each other, the formed bonding surface is greater than the bonding surface formed by directly bonding the first aperture of the first through-hole contact portion 602 and the second aperture 204 of the second through-hole contact portion 603, and thus the bonding strength is enhanced and the conductivity between the first through-hole contact portion 602 and the second through-hole contact portion 603 is improved. The first interface metal layer 201 and the second interface metal layer 202 are made of, for example, a conductive metal such as copper. Their formation methods may include, for example, physical vapor deposition (PVD), chemical vapor deposition (CVD), electroplating, chemical plating, and so on. The formation method of the first through-hole contact portion 602 may be, for example, as follows: a light-emitting mesa 601 and a first insulating layer 611A are formed on a temporary substrate, then the first insulating layer 611A is etched to form through-holes leading to the bottom of the light-emitting mesa 601, subsequently, a metal is deposited in the through-holes, and finally the apertures of the through-holes are planarized to form the bonding surface.

Furthermore, the first through-hole contact portion 602 is used to electrically connect the drive circuit 606 with the bottom (herein is the reflective mirror layer 615) of the epitaxial layer 601 (or light-emitting mesa) of the micro-LED array after bonding with the second through-hole contact portion 603, thereby connecting the epitaxial layer 601 to the anode 610. Herein, a first metal barrier layer 617 is arranged between the first through-hole contact portion 602 and the reflective mirror layer 615. The first metal barrier layer 617 can prevent the metal in the first through-hole contact portion 602 from diffusing into the epitaxial layer 601 or the first insulating layer 611A through the reflective mirror layer 615 and other layers (e.g., the bottom transparent electrode layer) that may be arranged therebetween, or from oxidizing. If the metal in the first through-hole contact portion 602 diffuses into the epitaxial layer 601, the luminous performance of the epitaxial layer 601 will be affected; if it diffuses into the first insulating layer 611A, the insulating effect of the first insulating layer 611A will be affected, thereby leading to leakage current or even short circuits; if the metal in the first through-hole contact portion 602 oxidizes, it may cause poor contact between the first through-hole contact portion 602 and the reflective mirror layer 615, or even result in an open circuit in the electrical circuit to the epitaxial layer 601. From this, it can be seen that by arranging the first through-hole contact portion 602 according to the present disclosure, metal diffusion in the first through-hole contact portion 602 can be effectively avoided, and thus risks such as reduced luminous performance, short circuit, and open circuit of the micro-LED can be effectively prevented. The combination of the first metal barrier layer 617 and the first barrier layer and the second barrier layer of the reflective mirror layer can further enhance the metal barrier and antioxidant effects.

The second electrode 610, herein is the anode, and is electrically connected with the drive circuit 606 through a third through-hole contact portion 614 passing through the first insulation layer 611A and the second insulation layer 611B. The anode 610 may be, for example, connected to an external power source or control source to be used to supply power for the micro-LED chip 600 or control the micro-LED chip 600. Herein, the third through-hole contact portion 614 may include a plurality of through-hole contact portions to be used to connect the second epitaxial layers 601C of a plurality of light-emitting mesas to the anode 610. Herein, it is exemplarily shown that the third through-hole contact portion 614 includes two through-hole contact portions, but this is merely an example, and other numbers of the third through-hole contact portions 614 are also conceivable. The third through-hole contact portion 614 may be formed either before hybrid bonding or after hybrid bonding. If the third through-hole contact portion 614 is formed before hybrid bonding, then the upper and lower portions of the third through-hole contact portion 614 are first formed in the upper stacked layer 600A and the lower stacked layer 600B, respectively, and then after hybrid bonding, these two portions are connected through the through-hole contact portion, and then the first insulating layer 611A is etched from above to form the anode 610 on the third through-hole contact portion 614. If the third through-hole contact portion 614 is formed after hybrid bonding, then the first insulating layer 611A is etched from above to form through-holes leading to the drive circuit 606, metal is then deposited in the through-holes, then the third through-hole contact portion 614 is etched to form a recess, metal is then deposited in the recess to form the anode 610. The anode 610 and its connecting components may be made of materials such as metals (e.g., copper, silver, or aluminum), graphene, ITO, aluminum doped zinc oxide (AZO), or fluorine doped tin oxide (FTO), or any combination of the above materials.

The first bonding mark 609A is arranged in the first insulating layer 611A and exposes the first marking surface, i.e., the aperture of the first bonding mark. The function of the first bonding mark 609A in the upper stacked layer 600A is to serve as a mark aligned with the second bonding mark 609B in the lower stacked layer 600B, and thus precise hybrid bonding is achieved, and the second bonding mark 609B is arranged in the second insulating layer 611B and exposes the second marking surface, i.e., the aperture of the second bonding mark. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

Microlens 605 is arranged above the light-emitting mesa 601 to be used to shape such as focus or collimate the light emitted therefrom. The microlens includes a lens portion 605A and a spacer portion 605B. The lens portion 605A is arranged at the outermost side, i.e. the topmost and configured to shape light from the light-emitting mesa 601. The spacer portion 605B is arranged between the lens portion 605A and the light-emitting mesa 601 to adjust the focal position of the lens portion 605A, for example, parameters such as the thickness of the spacer portion 605B and the curvature of the lens portion 605A, etc. are adjusted, such that the focal point of the lens portion 605A is precisely located in the light-emitting mesa 601 of the micro-LED. The width of the microlens 605 is, for example, 0.8 μm to 4 μm, preferably 1 μm to 3 μm. The distance between the lens portion 605A and the cathode 604 is, for example, 0.05 μm to 4 μm, preferably 0.1 μm to 0.3 μm. The microlens 605 corresponds one-to-one with the light-emitting mesa 601. Meanwhile, in the present embodiment, adjacent microlenses 605 have gaps between them and their bottoms are connected with each other. The bottoms of the gaps are higher than the top of the light-emitting mesa 601 or higher than the bottom of the light-emitting layer 601B of the light-emitting mesa 601, and the lens portion 605A is located above the cathode 604. The microlens 605 may be formed through a plurality of deposition steps, during the formation process of the microlens, a SiO₂ film layer is first deposited, then ion etching is performed, and the microlens is formed at the positions on the surface of the transparent conductive layer 608 corresponding to each light-emitting mesa 601.

### Lower Stacked Layer

The lower stacked layer 600B includes a second insulating layer 611B, a second through-hole contact portion 603, a drive circuit 606, and a second bonding mark 609B. The various components are described below, respectively.

The second insulating layer 611B is arranged on the drive circuit 606 and is configured to accommodate the second through-hole contact portion 603. The material of the second insulating layer 611B may be, for example, silicon dioxide, silicon nitride, high-k dielectric materials (e.g., hafnium oxide, aluminum oxide, etc.), and so on. The second insulating layer 611B may be, for example, formed on the drive circuit 606 through methods such as thermal oxidation or chemical vapor deposition (CVD), etc. The thickness of the second insulating layer 611B may be, for example, 1 μm to 3 μm, preferably 2 μm, and more preferably 0.6 μm to 1.4 μm. Furthermore, the second insulating layer 611B may be planarized at interface A-A (e.g., through chemical mechanical polishing CMP) to facilitate hybrid bonding with the first insulating layer 611A.

The second insulating layer 611B is transparent to light emitted from the light-emitting mesa 601. In some embodiments, the second insulating layer 611B is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the second insulating layer 611B may facilitate the passage of light emitted from the light-emitting mesa 601. In some embodiments, the second insulating layer 611B may include a plurality of portions, such as three embedded dielectric portions and two adhering dielectric portions. The embedded dielectric portions refer to the dielectric layers surrounding each light-emitting diode structure; while the adhering dielectric portions refer to the dielectric layers between two light-emitting diode structures. The embedded dielectric portions and the adhering dielectric portions may have the same or different compositions. ·The second through-hole contact portion 603, which passes through the second insulating layer 611B. The second through-hole contact portion 603 is configured to hybrid bond with the first through-hole contact portion 602 at interface A-A, and thereby electrically connecting the bottom of the light-emitting mesa 601, particularly the second epitaxial layer 601C to the second electrode 610 (herein is the anode). The second through-hole contact portion 603 is preferably a cylindrical through-hole, and the inner wall and/or central space is filled with a conductor, such as metallic copper. The diameter of the second through-hole contact portion 603 is of 0.5 μm to 2.2 μm, preferably 0.8 μm to 1.6 μm. The second through-hole contact portion 603 may be planarized at interface A-A (e.g., through chemical mechanical polishing CMP) to facilitate hybrid bonding with the first through-hole contact portion 602. Furthermore, in order to enhance the bonding strength and improve the conductivity between the second through-hole contact portion 603 and the first through-hole contact portion 602, a second interface metal layer may be arranged at the second aperture of the second through-hole contact portion 603, and the area of the second interface metal layer is greater than the area of the second aperture. Similarly, a first interface metal layer may be arranged at the first aperture of the first through-hole contact portion 602, and the area of the first interface metal layer is greater than the area of the first aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer are made of, for example, a conductive metal such as copper. Their formation methods may include, for example, physical vapor deposition (PVD), chemical vapor deposition (CVD), electroplating, chemical plating, and so on. The formation method of the second through-hole contact portion 603 may be, for example, as follows: a drive circuit 606 is provided, then a second insulating layer 611B is formed on the drive circuit 606, then the second insulating layer 611B is etched to form through-holes leading to the top of the drive circuit 606, subsequently, a metal is deposited in the through-holes, and finally the apertures of the through-holes are planarized to form the bonding surface.

Furthermore, the second through-hole contact portion 603 is used to electrically connect the drive circuit 606 with the bottom (herein is the reflective mirror layer 615) of the epitaxial layer 601 (or light-emitting mesa) of the micro-LED array after bonding with the first through-hole contact portion 602, thereby connecting the epitaxial layer 601 to the anode 610. Herein, a first metal barrier layer 617 is arranged between the second through-hole contact portion 603 and the drive circuit 606. The first metal barrier layer 617 can prevent the metal in the second through-hole contact portion 603 from diffusing into the drive circuit 606 or the second insulating layer 611B, or from oxidizing. If the metal in the second through-hole contact portion 603 diffuses into the drive circuit 606, then the electrical performance of the drive circuit will be affected, such as causing a short circuit; if it diffuses into the second insulating layer 611B, then the insulating effect of the second insulating layer 611B will be affected, thereby leading to leakage current or even short circuits; if the metal in the second through-hole contact portion 603 oxidizes, it may cause poor contact between the second through-hole contact portion 603 and the drive circuit 606, or even result in an open circuit in the electrical circuit to the drive circuit 606. From this, it can be seen that by arranging the second through-hole contact portion 603 according to the present disclosure, metal diffusion in the second through-hole contact portion 603 can be effectively avoided, and thus risks such as short circuits or open circuits in the drive circuit 606. The combination of the first metal barrier layer 617 and the first barrier layer and the second barrier layer of the reflective mirror layer can further enhance the metal barrier and antioxidant effects.

The drive circuit 606 is electrically connected with the second through-hole contact portion 603 to electrically connect the second epitaxial layer 601C of the light-emitting mesa 601 to the anode 610. For this purpose, the drive circuit 606 has conductive line layers to be used for interconnecting each second through-hole contact portion 603 to the corresponding anode 610. The drive circuit 606 may be, for example, a thin-film transistor (TFT) drive circuit and may include 2T1C drive circuit, 3T1C drive circuit, and 5T2C drive circuit. The drive circuit 606 is configured to drive the micro-LEDs, such as controlling the switching on/off and brightness of the micro-LEDs. The drive circuit 606 may include, for example, transistors, capacitors, a conductive line layer, an insulating layer, and a metal layer, etc. The conductive line layer is formed on the substrate and configured to supply power to the micro-LED array. The insulating layer is formed on the conductive line layer, through-holes are arranged in the insulating layer, and through-hole contact portions (e.g., IC copper pillars) are arranged in the through-holes to be used for electrically connecting the conductive line layer with the micro-LED array. The metal layer is used for bonding and electrically contacting the micro-LEDs. The conductive line layer, the metal layer, and the insulating layer may be formed on substrate through deposition methods such as physical vapor deposition (PVD) and chemical vapor deposition (CVD).

The second bonding mark 609B is arranged in the second insulating layer 611B and exposes the second marking surface, i.e., the aperture of the second bonding mark. The function of the second bonding mark 609B in the lower stacked layer 600B is to serve as a mark aligned with the first bonding mark 609A in the upper stacked layer 600A, and thus precise hybrid bonding is achieved. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

After the formation of the lower stacked layer 600B and the upper stacked layer 600A, the lower stacked layer 600B is jointed with the upper stacked layer 600B through hybrid bonding, such that the first through-hole contact portion 602 is bonded with the second through-hole contact portion 603 and the first insulating layer 611A is bonded with the second insulating layer 611B, optionally the first bonding mark 609A is bonded with the second bonding mark 609B, and the upper and lower portions of the third through-hole contact portion 614 are bonded with each other. The present disclosure solves the technical problem encountered in manufacturing upside-down arranged trapezoidal light-emitting mesa with a large upper surface and a small lower surface, i.e., the electrical connection problem of the light-emitting mesa to the driving circuit, by respectively fabricating the upper stacked layer 600A and the lower stacked layer 600B and then jointing them with each other through hybrid bonding. The present disclosure achieves electrical connection of the light-emitting mesa 601 to the drive circuit 606 through hybrid bonding, allowing both the upper stacked layer 600A and the lower stacked layer 600B can be manufactured from the surface opposed to the hybrid bonding surface, i.e., interface A-A, towards the hybrid bonding surface, so that high-quality conductive structures, such as the first to third through-hole contact portions (such as IC copper pillars) are achieved, and the length of the conductive structure can also be flexibly selected.

An exemplary of the hybrid bonding may include the following two parts:
(1) Dielectric-to-dielectric bonding (i.e., bonding between the first insulating layer 611A and the second insulating layer 611B): at room temperature, extremely flat and smooth dielectric surfaces obtained through chemical mechanical polishing (CMP) are brought into close contact at room temperature after activation through methods such as plasma treatment to achieve preliminary bonding.
(2) Metal-to-metal bonding (i.e., bonding between through-hole contact portions): after completing the dielectric-to-dielectric bonding, the upper and lower stacked layers are heated to 200° C.-400° C. for annealing treatment to strengthen the dielectric bonding and promote metal-to-metal bonding, thereby achieving hybrid bonding.

FIGS. 4A-4G illustrate the method for forming the light-emitting mesa according to the present disclosure.

As shown in FIG. 4A, in step S1, an epitaxial wafer is provided, and the epitaxial wafer includes a transparent conductive layer 101, a first epitaxial layer 102, an light-emitting layer 103, and a second epitaxial layer 104 stacked on each other.

As shown in FIG. 4B, in step S2, a photoresist 400 is coated on the epitaxial wafer. A soft bake may be performed after coating photoresist, this step is to heat the photoresist at a specific temperature (typically 80° C.-120° C.). The primary purpose of the soft bake is to remove solvent components from the photoresist, cure the photoresist, enhance adhesion between the photoresist and the epitaxial wafer, meanwhile also reduce exposure time errors during subsequent exposure processes.

As shown in FIG. 4C, in step S3, the photoresist 400 is exposed and developed. The exposure process is as follows, for example, by using a lithography machine, the pattern on the designed mask is transferred onto the photoresist. A mask is a transparent or semi-transparent template with a specific pattern, and the pattern part, for example, can be passed through by light. According to the different types of lithography machines, exposure methods are mainly divided into optical exposure (e.g., ultraviolet light exposure, deep ultraviolet light exposure, etc.) and electron beam exposure. The principle of optical exposure is to use ultraviolet light and other light to irradiate the photoresist through a mask, causing a chemical change in the photoresist in the illuminated area. Electron beam exposure is to use an electron beam to irradiate photoresist. Then the exposed photoresist is developed. The developer is a chemical solution that can dissolve photoresist, for positive photoresist, the developer dissolves the photoresist in the exposed portions; for negative photoresist, the developer dissolves the photoresist in the unexposed portions. For example, the way of development is as follows: the substrate coated with exposed photoresist is immersed in the developer for a certain period of time (typically ranging from tens of seconds to several minutes), or spray type development is used to make the developer uniformly act on the photoresist surface. After development, a structure corresponding to the mask pattern is formed on the photoresist. Herein, after development, the portions, e.g. the exposed portions A, on the epitaxial wafer that need to be etched are exposed.

The substrate with the exposed photoresist is immersed in the developer for a certain time (usually from tens of seconds to several minutes), or spray type development is used to ensure uniform action of the developer on the photoresist surface. After development, a structure corresponding to the mask pattern is formed on the photoresist. Herein, after development, for example, the portions that need to be etched on the epitaxial wafer are exposed, i.e., the exposed portion A is generated.

As shown in FIG. 4D, in step S4, the photoresist 400 is baked to generate a photoresist collapse B at the exposed portion A. The baking temperature is, for example, 120° C. to 140° C., preferably 130° C., and the baking time is 8 minutes to 12 minutes, preferably 10 minutes. The generation reasons for the photoresist collapse B are as follows: the photoresist at the edges of the exposed portion A gradually collapses toward the center during baking to form the photoresist collapse B, and the photoresist collapse B thins toward the center of the exposed portion A, thereby forming a smooth edge of the exposed portion A and improving the angle of subsequent etching. The structural characteristics caused by the photoresist collapse, for example, are that both the side surface inclination angle of the transparent conductive layer 101 and the side surface inclination angle of the first epitaxial layer 102 can be significantly reduced, for example, both are below 70°. When using the above temperature and baking time, both the side surface inclination angle of the transparent conductive layer 101 and the side surface inclination angle of the first epitaxial layer 102 can be further reduced, for example, both are below 65°.

As shown in FIG. 4E, in step S5, the transparent conductive layer 101 is etched in the first etching step to expose the first epitaxial layer 102, and the first epitaxial layer 102 is not etched during the first etching step. Herein, the edge of the transparent conductive layer 101 is etched to form the first inclined edge 100A. The first inclined edge 100A has a first taper angle X. Structural characteristics caused by step-by-step etching can be reflected, for example, in that the side surface inclination angle of the transparent conductive layer 101 is not equal to the side surface inclination angle of the first epitaxial layer 102.

As shown in FIG. 4F, in step S6, during the second etching step after the first etching step, the first epitaxial layer 102, the light-emitting layer 103, and the second epitaxial layer 104 are etched to form the second inclined edge 100B at the side surface of the light-emitting mesa, and the second inclined edge 100B has a second inclination angle Y, and the second inclination angle Y may be the same as the first inclination angle X, or different from the first inclination angle X. In the present embodiment, the second inclination angle Y is less than the first inclination angle X, and the first inclination angle X is greater than 70°, which is 80°, and the second inclination angle Y is less than 70°, which is 65°.

The second inclination angle Y and the first inclination angle X satisfy the following relationship:
d=(X*d1+Y*d2)/(d1+d2);
55°≤d≤75°, particularly 60°≤d≤70°,
where X is the inclination angle of the first inclined edge 100A, and Y is the inclination angle of the second inclined edge 100B of the first epitaxial layer 102, the light-emitting layer 103, and the second epitaxial layer 104, and d1 is the thickness of the transparent conductive layer 101, and d2 is the sum of the thicknesses of the first epitaxial layer 102, the light-emitting layer 103, and the second epitaxial layer 104, and d is the average inclination angle d over the entire thickness of the light-emitting mesa 100. According to the above equation, in the present embodiment, d1=d2/15, and d=65.9°.

Finally, as shown in FIG. 4G, in step S7, the photoresist is removed.

Herein, the light-emitting mesa formed according to the present disclosure has an optimized inclination angle, so that the aperture area can be increased and thus the aperture ratio of the micro-LED is improved.

Although some embodiments of the present disclosure have been described in the present application, however, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the disclosure and thus encompass methods and structures within the scope of these claims themselves and their equivalent variations.

What is claimed is:

1. A light-emitting mesa for a micro-LED, comprising:
a transparent conductive layer, a first epitaxial layer, a light-emitting layer and a second epitaxial layer arranged from a side of the light-emitting mesa facing away from a light extraction side toward a side of the light-emitting mesa facing the light extraction side,
wherein
the transparent conductive layer is arranged on the side of the light-emitting mesa facing away from the light extraction side;
the first epitaxial layer is arranged between the transparent conductive layer and the light-emitting layer;
the light-emitting layer is arranged between the first epitaxial layer and the second epitaxial layer, and the light-emitting layer is configured to emit light; and
the second epitaxial layer is arranged on the side of the light-emitting mesa facing the light extraction side,
wherein
an area of the second epitaxial layer is greater than an area of the first epitaxial layer,
a side surface of the light-emitting mesa has an inclined surface, and
an inclination angle of the inclined surface is 55° to 75°.

2. The light-emitting mesa according to claim 1, wherein
a side surface of the transparent conductive layer has a first slope, and
the first epitaxial layer has a second slope,
wherein the first slope is not equal to the second slope.

3. The light-emitting mesa according to claim 1, wherein
the inclination angle of the inclined surface is 60° to 70°.

4. The light-emitting mesa according to claim 2, wherein
a side surface of the second epitaxial layer and a side surface of the light-emitting layer have the second slope,
wherein corresponding inclination angles of the first slope and the second slope are both less than or equal to 70°.

5. The light-emitting mesa according to claim 4, wherein
the corresponding inclination angles of the first slope and the second slope are both less than or equal to 65°.

6. The light-emitting mesa according to claim 1, wherein
a maximum width at two ends of the inclined surface of the light-emitting mesa is 1.4 μm to 1.7 μm.

7. The light-emitting mesa according to claim 1, wherein
a depth of the light-emitting mesa is 0.3 μm to 0.7 μm.

8. The light-emitting mesa according to claim 1, wherein
a thickness of the transparent conductive layer is 600 nm to 1500 nm; and/or
a thickness of the first epitaxial layer is 80 nm to 120 nm; and/or
a thickness of the light-emitting layer is 280 nm to 400 nm; and/or
a thickness of the second epitaxial layer is 180 nm to 220 nm.

9. The light-emitting mesa according to claim 1, wherein
a side surface of the transparent conductive layer has a first inclined edge, and
side surfaces of the first epitaxial layer, the light-emitting layer, and the second epitaxial layer have a second inclined surface,
wherein
an end of the first inclined edge is connected with an end of the second inclined surface; or
a horizontal distance between the end of the first inclined edge and the end of the second inclined surface is less than or equal to 200 nm.

10. The light-emitting mesa according to claim 9, wherein
the first inclined edge has a first inclination angle X, and
the second inclined surface has a second inclination angle Y,
wherein the first inclination angle X and the second inclination angle Y satisfy following relationship:
d=(X*d1+Y*d2)/(d1+d2);
60°≤d≤70°,
wherein
d1 is a thickness of the transparent conductive layer,
d2 is a sum of thicknesses of the first epitaxial layer, the light-emitting layer, and the second epitaxial layer, and
d is an average inclination angle of the light-emitting mesa over an entire thickness.

11. The light-emitting mesa according to claim 1, wherein
a material of the transparent conductive layer is selected from a group comprising:
indium tin oxide, zinc oxide, or cadmium tin oxide.

12. A micro-LED chip, comprising:
the light-emitting mesa according to claim 1;
an insulating layer, accommodating the light-emitting mesa and through-hole contact portions;
a drive circuit, provided with a metal layer on a surface of the drive circuit, the drive circuit is provided with a plurality of through-hole contact portions, and the through-hole contact portions are electrically connected with the metal layer, and an array area of the micro-LED chip is bonded onto the drive circuit through a bottom conductive bonding layer, wherein the drive circuit further comprises a wiring stacked layer below the metal layer;
a first electrode, being electrically connected with the through-hole contact portions and being led out of the wiring stacked layer;
a passivation layer, covering at least a part of the side surface of the light-emitting mesa;
a bottom transparent conductive layer, located on a surface of the passivation layer and in electrical contact with the second epitaxial layer; and
a second electrode, located on a surface of the transparent conductive layer.

13. The micro-LED chip according to claim 12, wherein
the second electrode is a circular reflective electrode arranged around the light-emitting mesa.

14. The micro-LED chip according to claim 12, wherein
a polarity of the second electrode is opposite to a polarity of the first electrode.

15. The micro-LED chip according to claim 12, wherein
a material of the passivation layer is at least one of Si₃N₄, SiO₂, or Al₂O₃.

16. The micro-LED chip according to claim 12, wherein
a material of a substrate of the micro-LED chip is selected from a group comprising:
silicon (Si), silicon dioxide (SiO₂), silicon nitride (Si₃N₄), silicon carbide (SiC), gallium nitride (GaN), glass, aluminum nitride (AlN), sapphire (α-Al₂O₃), and germanium (Ge).

17. The micro-LED chip according to claim 12, wherein:
a material of the insulating layer is selected from a group comprising:
silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof; and/or
a material of the metal layer is selected from a group comprising:
aluminum (Al), copper (Cu), tungsten (W), silver (Ag), gold (Au), nickel (Ni), platinum (Pt), tantalum (Ta), and molybdenum (Mo).

18. The micro-LED chip according to claim 12, wherein
the through-hole contact portions comprise a first through-hole contact portion and a second through-hole contact portion,
the insulating layers comprise a first insulating layer and a second insulating layer,
the micro-LED chip comprises an upper stacked layer and a lower stacked layer,
wherein
the upper stacked layer comprises the first insulating layer, the light-emitting mesa, and the first through-hole contact portion,
the lower stacked layer comprises the second insulating layer, the second through-hole contact portion, and the drive circuit,
wherein
the lower stacked layer is jointed with the upper stacked layer through hybrid bonding, such that the first through-hole contact portion is bonded with the second through-hole contact portion, and the first insulating layer is bonded with the second insulating layer.

19. A method for forming a light-emitting mesa, comprising:
providing a temporary substrate;
forming an epitaxial layer on the temporary substrate, and the epitaxial layer comprise a second epitaxial layer in contact with the temporary substrate, a light-emitting layer arranged on the second epitaxial layer, and a first epitaxial layer arranged on the light-emitting layer;
forming a transparent conductive layer on the first epitaxial layer;
etching the transparent conductive layer in a first etching step to expose the first epitaxial layer, wherein the first epitaxial layer is not etched in the first etching step; and
etching the first epitaxial layer, the light-emitting layer, and the second epitaxial layer in a second etching step after the first etching step to form an inclined surface at a side surface of the light-emitting mesa, wherein an inclination angle of the inclined surface is 55° to 75°.

20. The method according to claim 19, wherein the second etching step comprises:
coating a photoresist over the transparent conductive layer and the first epitaxial layer that is exposed;
exposing the photoresist to form an exposed portion at a circumference of the transparent conductive layer;
baking the photoresist to generate a photoresist collapse at the exposed portion;
developing and rinsing the photoresist to pattern the photoresist; and
etching the first epitaxial layer, the light-emitting layer, and the second epitaxial layer through the photoresist that is patterned to form the light-emitting mesa.
